(19) United States
(12) Patent Application Publication
(10) Pub. No.: US 2006/0033577 A1
(43) Pub. Date: Feb. 16, 2006

(54) Amplifier circuit

(75) Inventors: Hideyuki Nakamizo, Tokyo (JP); Yoshikazu Yoshida, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Mitsubishi Denki Kabushiki Kaisha, Tokyo (JP)

(21) Appl. No.: 10/546,183

(22) PCT Filed: Mar. 26, 2003
(86) PCT No.: PCT/JP03/03675

§ 371 Date: Aug. 18, 2005

(51) Int. Cl. H03F 3/04

(52) U.S. Cl. 330/296; 330/288

(57) ABSTRACT

Bases of two grounded transistors are connected with each other to form a current mirror bias circuit. A signal is inputted to the base of one of the grounded transistors. To reduce the influence of β difference between the two grounded transistors by an amplifier to which the signal is outputted from the collector of the one of the grounded transistor, NPN transistors (Q4, Q5) are connected to the base electrodes of the two transistors and their collectors are connected to a power line (Vcc). Thus, the influence of β difference between the two grounded transistors can be reduced while the necessary power-supply voltage is maintained at a low level.

### TECHNICAL FIELD

This invention relates to an improvement of an amplifier that is useful particularly when it is used for high-frequency amplification applications.

### BACKGROUND ART

In a transistor circuit that amplifies a high-frequency signal, a phenomenon occurs such that the input capacitance of a base input circuit increases because of the influence of the electrostatic capacitance between a collector and a base. This phenomenon is called Miller effect.

As the frequency to be amplified becomes higher, this phenomenon becomes harder to ignore. Also because of the increase of a noise signal that occurs after a while, an amplification effect cannot be achieved. Thus, conventionally, various techniques for improving the characteristics of a high-frequency amplifier including the Miller effect have been proposed.

For example, in Patent Reference 1, in order to restrain changes of the passing phase of power even when input power increases to cause operation in a nonlinear operating area, PN junction of a diode or transistor is connected in a forward direction to a circuit that supplies bias to a base terminal of a high-frequency amplification transistor of ground amplification type, and a capacitor with small impedance is inserted between its anode and ground.

The detailed description of this circuit is given in Patent Reference 1. By causing a change in the capacitance between the base and emitter of the amplification transistor due to a change of input signal, and a change in the capacitance of the diode or transistor connected to the outside of the base, to increase or decrease in the ways opposite to each other, the apparent change in the input capacitance of the base electrode is reduced.

The circuit using the diode, disclosed in Patent Reference 1, is hereinafter referred to as diode-feed type circuit.

Patent Reference 1:

JP-A-9-260964, FIG. 1, FIG. 4, FIG. 8

### DISCLOSURE OF THE INVENTION

An amplifier according to this invention includes:

an NPN-type first transistor (Q1) having an emitter electrode grounded and having a collector electrode connected to a current control circuit (P1, P2);

an NPN-type second transistor (Q2) having an emitter grounded, the second transistor amplifying a signal inputted to its base electrode and outputting the amplified signal to its collector electrode;

an NPN-type fourth transistor (Q4) having an emitter electrode connected to a base electrode of the first transistor, having a base electrode connected to the collector electrode of the first transistor, and having a collector electrode connected to a power line; and

an NPN-type fifth transistor (Q5) having an emitter electrode connected to the base electrode of the second transistor, having a collector electrode connected to the power line, and having a base electrode connected to the base electrode of the fourth transistor.

With the above-described structure, since the fourth and fifth transistors have both a β difference compensation function and a diode function for diode feed, this amplifier can stably operate at an extremely low voltage.

### BRIEF DESCRIPTION OF THE DRAWINGS

FIG. 1 is a circuit diagram of an amplifier according to Embodiment 1 of this invention.

FIG. 2 is an explanatory graph for explaining the operation of the circuit shown in FIG. 1.

FIG. 3 is a circuit diagram of an amplifier according to Embodiment 2 of this invention.

FIG. 4 is a partial circuit diagram for explaining the operation of FIG. 3.

FIG. 5 is another partial circuit diagram for explaining the operation of FIG. 3.

### BEST MODE FOR CARRYING OUT THE INVENTION

Embodiment 1

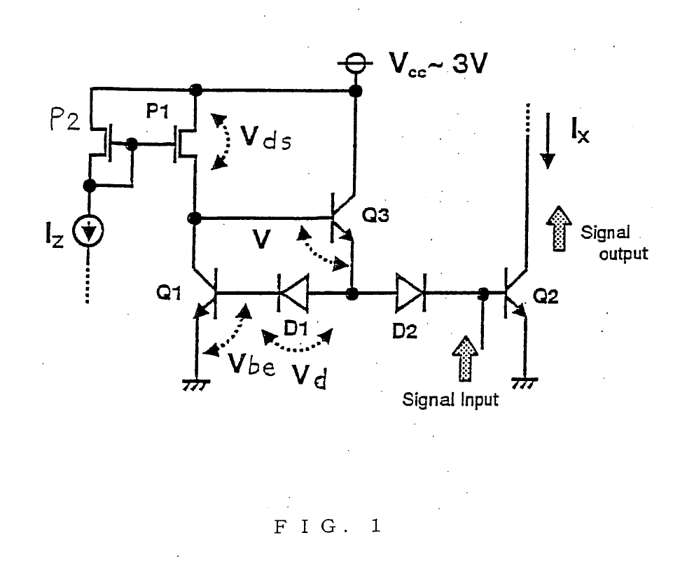

FIG. 1 shows a circuit structure of an amplifier according to Embodiment 1 of this invention, in which a diode-feed type circuit disclosed in Patent Reference 1 or the like is evolved to form a low-noise amplifier (hereinafter referred to as LNA). In FIG. 1, Iz is a current supplied from a constant-current circuit such as a band gap circuit, not shown. Using a current mirror circuit formed by PFETs (P1, P2) in FIG. 1, a current is supplied to a bias circuit of the LNA.

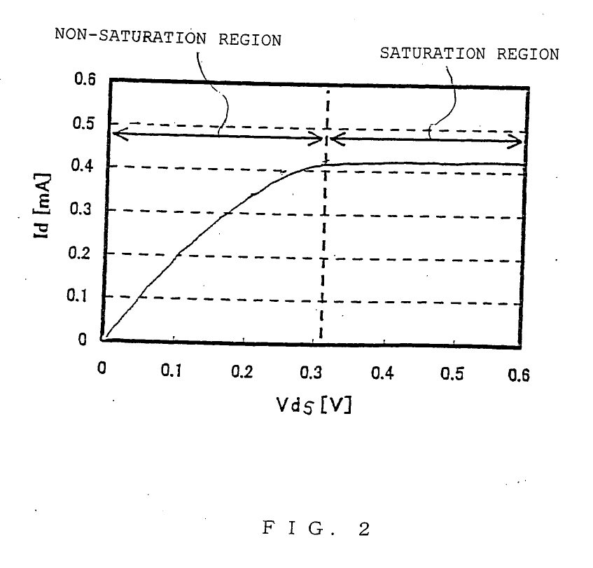

The PFETs (P1, P2) having the current mirror structure are used in a saturation region where a drain current Id is constant. The relation between a drain-source voltage Vds of the PFET and the drain current Id is as shown in FIG. 2. To allow the circuit to operate in the saturation region, Vds must be 0.3 V or higher.

Base-emitter voltages Vbe of a transistor Q3 and a transistor Q1, and an anode-cathode forward voltage Vd of a diode D1 is approximately 0.8 V when the circuit is used under typical conditions. However, it may exceed 0.9 V because of changes in temperature and process variance (difference between individual circuits generated in the manufacturing process).

As is clear from FIG. 1, all the voltage Vbe of the transistor Q1, the voltage Vd of the diode D1, the voltage Vbe of the transistor Q3 and the voltage Vds of the PFET (P1) are added in series. Therefore, to allow the circuit to stably perform a desired operation, a power-supply voltage Vcc must cause the circuit to operate within a range that satisfies the following relational expression of Vbe, Vd and Vds.
Vcc>2Vbe+Vd+Vds=3.0(V) (3)

Therefore, as a certain margin is considered so as to prevent any failure to satisfy the expression (3) because of temperature and process variance, the power-supply voltage to be used must be sufficiently higher than 3 V.

If the power-supply voltage is insufficient, for example, a sufficient drain-source voltage Vds of the PFET (P1) of the current mirror that supplies a current to the bias circuit cannot be secured and a desired current cannot be supplied. The entire circuit cannot perform a desired operation.

The transistors Q1, Q2 and Q3 are referred to as NPN-type first, second and third transistors, respectively. The diodes D1 and D2 are referred to as first and second diodes, respectively. The circuit of the PFETs (P1, P2) is referred to as current control circuit.

Embodiment 2

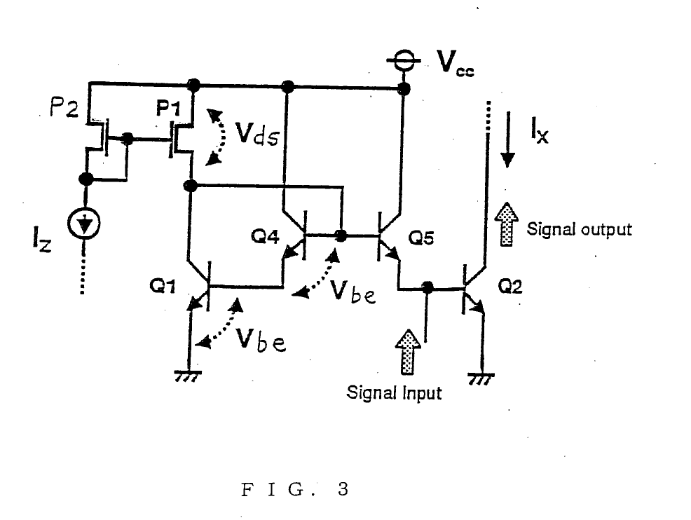

An amplifier according to Embodiment 2 of this invention is shown in FIG. 3. The circuit of this embodiment operates stably at a power-supply voltage lower than the power-supply voltage that is necessary for the circuit of Embodiment 1.

In FIG. 3, emitters of NPN transistors Q4 and Q5 are connected to bases of transistors Q1 and Q2, respectively, and collectors of the transistors Q4 and QS are connected to a power source Vcc. Bases of the transistors Q4 and Q5 are connected to each other. To balance a current mirror formed by the transistors Q1 and Q2, transistors that achieve an emitter size ratio of Q4:Q5 approximately equal to 1:M (which will be described later) are used as the transistors Q4 and Q5.

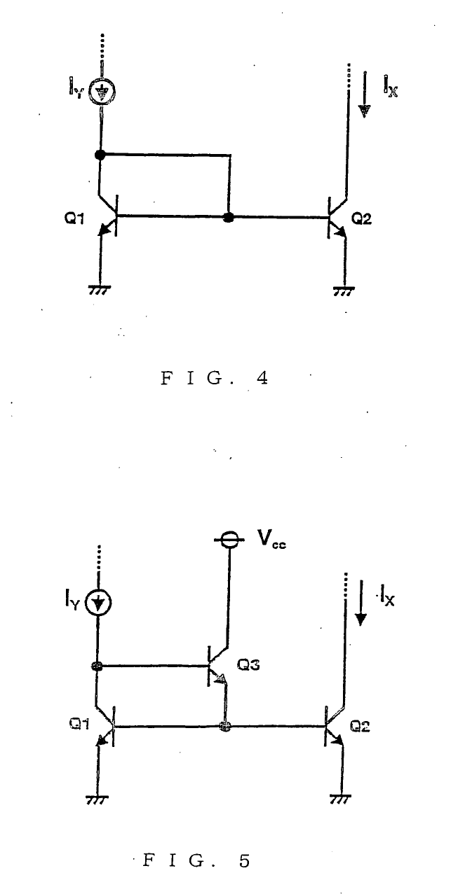

To facilitate understanding of the operation of the circuit shown in FIG. 3, circuit diagrams showing the principle of the current mirror circuit are given in FIGS. 4 and 5 and its operation will now be described. In FIGS. 4 and 5, the emitter size ratio of the transistors Q1 and Q2 is, for example, Q1:Q2=1:M. FIG. 5 shows a case where a β compensation transistor Q3 is additionally arranged in the circuit of FIG. 4. A current Ix turned back by each current mirror circuit is expressed by the following equations.

In the case of FIG. 4:
Ix=M*{1−(M+1)/(β+M+1)}*Iy (1)

In the case of FIG. 5:
Ix=M*{1−(M+1)/(β²+β+M+1)}*Iy (2)

Here, β represents the current gain of the transistor. Usually, the value of β largely varies within a range of approximately 150 to 250 because of changes in temperature and process variance generated in the semiconductor manufacturing process. Iy represents a reference current of the current mirror circuit.

As can be understood from the equations (1) and (2), the circuit of FIG. 5 is less dependent on β than the circuit of FIG. 4 is. In other words, the circuit of FIG. 5 is resistant to the difference in β.

The contribution of β difference of the bias circuit to Ix in FIG. 3 is totally the same as in the case of the equation (2). In short, the transistors Q4 and Q5 of FIG. 3 have the function of the β difference compensation transistor Q3 of the bias circuit described with reference to FIG. 5.

According to the circuit of FIG. 3, the power-supply voltage Vcc necessary for performing a desired operation is expressed as follows, using base-emitter voltage Vbe of the transistor and the drain-source voltage Vds of the PFET (P1).
Vcc>2Vbe+Vds=2.1(V) (4)

In the circuit of FIG. 3, since the transistors Q4 and Q5 have both the β difference compensation function and the diode function for bias feed, the number of vertically stacked transistors within the bias circuit (the number of series transistors inserted between the power line and ground) can be two. As a result, a sufficient drain-source voltage Vds of the PFET (P1) of the current mirror that supplies a current to the bias circuit can be secured even when the power-supply voltage of the circuit is lower than 3 V. Thus, larger temperature changes and process variance can be tolerated, and an amplifier or low-noise amplifier (LNA) that achieves both β difference compensation of the bias circuit and improvement in saturation characteristics can be realized.

The transistors Q1, Q2, Q4 and Q5 are referred to as NPN-type first, second, fourth and fifth transistors, respectively.

### INDUSTRIAL APPLICABILITY

This invention can be applied not only to a low-noise amplifier (LNA) but also all the circuits that handle particularly high frequencies and need high saturation characteristics, for example, a high-power amplifier or driver amplifier.

1-5. (canceled)

6. An amplifier comprising:
an NPN-type first transistor having an emitter electrode grounded and having a collector electrode connected to a current control circuit;
a first diode having a cathode electrode connected with a base electrode of the first transistor;
a second diode having an anode electrode connected with an anode electrode of the first diode;
an NPN-type second transistor having a base electrode connected with a cathode electrode of the second diode and having an emitter electrode grounded, the second transistor amplifying a signal input to the base electrode and outputting the amplified signal to its collector electrode; and
a bypass wiring that electrically connects the anode electrode of the first diode and the anode electrode of the second diode with the collector electrode of the first transistor and the current control circuit.

7. The amplifier as claimed in claim 6, further comprising an NPN-type third transistor having an emitter electrode connected to the anode electrode of the first diode and the anode electrode of the second diode and having a base electrode connected to the collector electrode of the first transistor, and provided on the bypass wiring.

8. The amplifier as claimed in claim 6, wherein the current control circuit is a constant-current circuit formed by two PFETs having gate electrodes connected with each other.

9. An amplifier comprising:
an NPN-type first transistor having an emitter electrode grounded and having a collector electrode connected to a current control circuit;
a second transistor having an emitter grounded, the second transistor amplifying a signal input to its base electrode and outputting the amplified signal to its collector electrode;
an NPN-type fourth transistor having an emitter electrode connected to a base electrode of the first transistor, having a base electrode connected to the collector electrode of the first transistor, and having a collector electrode connected to the power line; and
an NPN-type fifth transistor having an emitter electrode connected to the base electrode of the second transistor, having a collector electrode connected to the power line, and having a base electrode connected to the base electrode of the fourth transistor.

10. The amplifier as claimed in claim 9, wherein the current control circuit is a constant-current circuit formed by two PFETs having gate electrodes connected with each other.

11. The amplifier as claimed in claim 9, wherein an emitter size ratio of the fourth transistor and the fifth transistor is the same as the emitter size ratio of the first transistor and the second transistor.

12. The amplifier as claimed in claim 9, wherein an emitter size ratio of the fourth transistor and the fifth transistor is substantially the same as the emitter size ratio of the first transistor and the second transistor.
